(19) United States
(12) Patent Application Publication
(10) Pub. No.: US 2010/0097150 A1
(43) Pub. Date: Apr. 22, 2010

(54) PLL CIRCUIT

(76) Inventors: Keisuke Ueda, Tokyo (JP); Toshiya Uozumi, Tokyo (JP); Satoru Yamamoto, Tokyo (JP); Mitsunori Samata, Tokyo (JP); Russell P. Mohn, Tarrytown, NY (US); Aleksander Dec, Tarrytown, NY (US); Ken Suyama, Tarrytown, NY (US)

Correspondence Address: MATTINGLY, STANGER, MALUR & BRUNDIDGE, P.C.;ATTORNEYS AT LAW, Suite 370, 1800 Diagonal Road, Alexandria, VA, 22314, US

(21) Appl. No.: 12/252,443

(22) Filed: Oct. 16, 2008

(51) Int. Cl. H03L 7/08

(52) U.S. Cl. 331/25

(57) ABSTRACT

A technique for suppressing quantization noise generated due to digitizing an analog circuit in a PLL circuit is provided. The PLL circuit comprises: a digital phase frequency detector which detects (compares) phases and frequencies of a reference signal and a frequency-divided signal and converts the same to a digital value; a digital loop filter which eliminates high-frequency noise components from an output of the digital phase frequency comparator; a digital-analog converter which converts a digital value of an output of the digital loop filter to an analog value; an analog filter which eliminates a high-frequency noise component from an output of the digital-analog converter; a voltage controlled oscillator whose frequency is controlled based on an output of the analog filter; and a frequency divider which divides the frequency of the voltage controlled oscillator and outputs the frequency-divided signal.

### TECHNICAL FIELD OF THE INVENTION

The present invention relates to a PLL (Phase Locked Loop) circuit. More particularly, the present invention relates to a technique for suppressing noise to be problematic in digitizing PLL circuits.

### BACKGROUND OF THE INVENTION

RF-IC used in cell phones and wireless LAN still has high potential for development. Currently, development of RF-IC has been progressed to 1-chip integration with a BB-IC (Baseband IC). Accordingly, it has been required to develop RF-IC in a sub-micron CMOS process used for BB-IC. Since RF-ICs are often analog circuits, current and area of an RF-IC tend to be increased when using the sub-micron CMOS process where device deviations are increased. More particularly, in microfabrication, device variations and increases of consumption current and area in an analog circuit due to an increase of gate capacitance will be problematic. Replacing the analog circuit with a digital circuit is one possible countermeasure.

There are techniques regarding a PLL circuit like this such as those described by: Thomas A. D. Riley et al., “A simplified continuous phase modulator technique”, IEEE Transactions on Circuit and Systems II, Analog and Digital Signal Processing, Volume 41, Issue. 5, May 1994 (Non-Patent Document 1); Scott E. Meninger and Michael H. Perrott, “A 1-MHZ Bandwidth 3.6-GHz 0.18-μm CMOS Fractional-N Synthesizer Utilizing a Hybrid PFD/DAC Structure for Reduced Broadband Phase Noise”, IEEE Journal of Solid-State Circuits, Volume 41, Issue 4, April 2006 (Non-Patent Document 2); and Robert Bogdan Staszewski et al., “All-digital PLL and transmitter for mobile phones”, IEEE Journal of Solid-State Circuits, Volume 40, Issue 12, December 2005 (Non-Patent Document 3). Non-Patent Document 1 relates to a technique for superimposing phase modulation on a fractional PLL. Non-Patent Document 2 relates to a technique for eliminating Sigma-Delta (ΣΔ) noise. Non-Patent Document 3 relates to a technique for an AD-PLL (All Digital Phase-Locked Loop).

### SUMMARY OF THE INVENTION

Meanwhile, after the inventors of the present invention studied on the techniques of PLL circuit as mentioned above, the following facts were revealed.

FIG. 12 shows a configuration of a general charge-pump PLL circuit (CP-PLL).

The CP-PLL shown in FIG. 12 comprises: a phase frequency detector (PFD) 1201; a charge pump (CP) 1202; an analog loop filter (ALF) 1203; a voltage controlled oscillator (VCO) 1204; and a divider (DIV) 1205.

In the CP-PLL shown in FIG. 12, a frequency of an output of the VCO 1204 is divided by the DIV 1205 and phases of the divided signal DIV and a reference signal REF (reference) are detected (compared) by the PFD (1201). A detection (comparison) result, i.e., an output of the PFD 1201 is a signal in pulse-like shape having a width corresponding to a phase difference, and the signal switches a switch of the CP 1202 so that a current flowing through the ALF 1203 is adjusted. The ALF 1203 removes high-frequency components of a current pulse signal to convert the same to a voltage. An output voltage of the ALF 1203 corresponding to a phase difference is inputted to a control part of the VCO 1204 so that an oscillation frequency of the VCO 1204 is controlled. Feedback is continued until the frequency of the divided signal DIV and the frequency of the reference signal REF match to each other, and thus a clock having a frequency obtained by multiplying the reference frequency REF by the frequency divide rate is obtained as a PLL output (output). The frequency of the PLL output is controlled by changing the frequency divide rate of the DIV 1205. While the frequency divide rate can be only an integer value, it can be a decimal number when using a fractional system. By the fractional system, the frequency divide rate after time-averaged over frequency becomes a fractional value by switching the frequency divide rate of the DIV 1205 at a frequency.

FIG. 13 shows a configuration example of an all-digital PLL circuit (AD-PLL) studied as a premise of the present invention.

The AD-PLL shown in FIG. 13 is an All Digital PLL in which the PFD and ALF etc. are digitized, as compared with the above-described CP-PLL. The AD-PLL shown in FIG. 13 comprises: a digital phase frequency detector (DPFD: Digital PFD) 1301; a digital loop filter (DLF) 1302; a digital controlled oscillator (DCO) 1303; and a frequency divider (DIV) 1304.

In the AD-PLL shown in FIG. 13, the DPF 1301 directly converts a phase difference between the phase-divided signal DIV and the reference signal REF to digital. The DLF 1302 eliminates unnecessary component to control the DCO 1303. As compared with the CP-PLL mentioned above, the AD-PLL has an advantage of reducing area by process scaling. Specifically, the area can be largely reduced by using a digital loop filter (DLF) as a loop filter. Frequency switching is realized by changing a frequency divide rate of the DIV 1304 or inputting a digital signal after phase detection. Meanwhile, since the phase difference is discretely controlled, quantization noise is generated so that a phase noise characteristics of the output is deteriorated. By inserting a Sigma Delta (ΣΔ) modulator before the DCO 1303, it is possible to suppress noise characteristics near an oscillation frequency according to a noise-shaping effect of the ΣΔ modulator.

PLL circuit supplies stable clocks inside an IC, and its performance is determined by an oscillation frequency range, phase noise, consumption current, area and so on. Especially, in the case of a transmission system (e.g., Non-Patent Document 1) which superimposes phase modulation on a PLL of fractional system, high performance is required for every factor.

When performing a phase division using the fractional system, the phase divide rate is changed even in a frequency stable state (steady state), and thus there arises a phase difference at an output of the PFD or the DPFD. FIG. 14 shows output waveforms of the PFD/DPFD in a steady state. In FIG. 14, REF represents a reference signal to be inputted to the PFD/DPFD, DIV represents a phase-divided signal to be inputted to the PFD/DPFD, and OUT represents an output of the PFD/DPFD. As shown in FIG. 14, a cyclic phase difference appears in OUT, which is the output of the PFD/DPFD. This phase difference appears in the output of the PLL as noise.

In the conventional CP-PLL circuit using an ALF, noise in the phase-stable state is eliminated by adding a predicted phase difference to a CP current from the control part of the DIV (e.g., Non-Patent Document 2). However, since the CP and ALF are weak to characteristics variations, it is difficult to eliminate noise. FIG. 15 shows a noise suppression circuit using a CP, and FIG. 16 and FIG. 17 are conceptual diagrams showing CP output fluctuation due to characteristics variations. As shown in FIG. 15, by inputting a signal same as “PFD UP” (or “PFD DOWN”) to “DAC DOWN” (or “DAC UP”), in other words, by drawing out a current, which is same as that to be drawn into the CP, from the CP, noise is cancelled. However, due to variations in characteristics of the elements configuring the circuit, there occurs delay and fluctuations of current value. Therefore, when delay occurs between “PFD UP” and “DAC DOWN”, an LPF output voltage (out) is fluctuated as shown in FIG. 16. Also, when an error occurs in a voltage value of “DAC DOWN” (or “DAC UP”), the LPF output (out) is fluctuated as shown in FIG. 17.

In addition, in the AD-PLL using a DLF, quantization noise and operation clock appear as phase noise. FIGS. 18A and 18B are conceptual diagrams showing deterioration of phase noise characteristics due to quantization noise. FIG. 18A shows a part of a configuration of an AD-PLL and FIG. 18B shows a relationship of noise power and an offset frequency. In FIG. 18B, the curve shown by a dotted line represents DCO noise (Natural DCO noise). And, the curve shown by a solid line represents noise obtained by combining the DCO noise and quantization noise (Natural DCO noise+Quantization noise). Not that, the origin on the X axis of offset frequency corresponds to an oscillation frequency. Further, spurious noise due to the clock (“DLF Clock” in FIG. 18B) inputted to the DLF 1302 is appeared in the noise characteristics shown by the solid line in FIG. 18B.

FIGS. 19A and 19B are conceptual diagrams showing a noise shaping by a ΣΔ modulator and deterioration of phase noise characteristics. FIG. 19A shows a part of a configuration of an AD-PLL, and FIG. 19B shows the relation between the Noise Power and Offset Frequency. In FIG. 19B, the curve shown by a dotted line represents DCO noise (Natural DCO noise), and the curve shown by a solid line represents noise obtained by combining the DCO noise and quantization noise (Natural noise+Quantization noise). Note that, the origin of the X axis of offset frequency corresponds to an oscillation frequency. As shown FIGS. 19A and 19B, by using the ΣΔ modulator 1901 before the DCO 1303, the noise characteristics near the oscillation frequency are suppressed according to the noise-shaping effect. However, noise characteristics of far side is deteriorated (noise of higher offset frequency is increased) so that it becomes an interfering wave to adjacent channels.

Accordingly, an object of the present invention is to provide a technique capable of suppressing quantization noise generated due to digitizing an analog circuit of a PLL circuit.

The above and other objects and novel characteristics of the present invention will be apparent from the description of this specification and the accompanying drawings.

The typical ones of the inventions disclosed in this application will be briefly described as follows.

Namely, a PLL circuit of a typical embodiment comprises: a digital phase frequency detector (comparator) which detects (compares) phases and frequencies of a reference signal and a feedback signal and converts the same to a digital value; a digital loop filter which eliminates high-frequency noise components from an output of the digital phase frequency detector; a digital-analog converter which converts a digital value of an output of the digital loop filter to an analog value; an analog filter which eliminates a high-frequency noise component from an output of the digital-analog converter; an oscillator whose frequency is controlled based on an output of the analog filter; and a frequency divider which divides the frequency of the oscillator and outputs the feedback signal.

According to a typical embodiment, quantization noise generated due to digitizing a PLL circuit can be suppressed.

### BRIEF DESCRIPTIONS OF THE DRAWINGS

FIG. 1 is a block diagram showing a configuration example of a PLL (Phase-Locked Loop) according to a first embodiment of the present invention;

FIG. 2 is a circuit diagram showing a configuration example of a digital phase frequency detector (DPFD) in the PLL circuit according to the first embodiment of the present invention;

FIG. 3 is a circuit diagram showing a configuration example of a time-to-digital control (TDC) included in the DPFD in the PLL circuit according to the first embodiment of the present invention;

FIG. 4 is a circuit diagram showing a configuration example of a Sigma-Delta modulator (ΣΔdiv) in the PLL circuit according to the first embodiment of the present invention;

FIG. 5 is a circuit diagram showing a configuration example of an analog filter (AnF) in the PLL circuit according to the first embodiment of the present invention;

FIG. 6 is a conceptual diagram showing phase noise characteristics in the case of using the analog filter (AnF) in the PLL circuit according to the first embodiment of the present invention;

FIG. 7 is a block diagram showing a configuration example of a PLL (Phase-Locked Loop) circuit according to a second embodiment of the present invention;

FIG. 8 is a circuit diagram showing a configuration example of an oscillator in the PLL circuit according to the second embodiment of the present invention;

FIG. 9 is a block diagram showing a configuration of a transceiver RF-IC (BRIGHT) for the pan-European digital cellular system GSM according to a third embodiment of the present invention;

FIG. 10 is a block diagram showing a configuration of a transceiver RF-IC (BRIGHT) for the pan-European digital cellular system EDGE according to the third embodiment of the present invention;

FIG. 11 is a block diagram showing a configuration of a transceiver RF-IC (BRIGHT) for the pan-European digital cellular system EDGE/WCDMA according to the third embodiment of the present invention;

FIG. 12 is a block diagram showing a configuration example of a general charge-pump PLL circuit (CP-PLL);

FIG. 13 is a block diagram showing a configuration example of an all-digital PLL circuit (AD-PLL) studied as a premise of the present invention;

FIG. 14 is a diagram showing output waveforms of a PFD/DPFD in a steady state in a fractional-N PLL circuit studied as a premise of the present invention;

FIG. 15 is a diagram showing a configuration example of a cancelling circuit by a CP in the fractional-N PLL circuit studied as a premise of the present invention;

FIG. 16 is a diagram showing fluctuations of an LPF output voltage due to delay in the cancelling circuit of FIG. 15;

FIG. 17 is a diagram showing fluctuations in the LPF output voltage due to a DAC output error in the cancelling circuit of FIG. 15;

FIGS. 18A-18B are diagrams showing a concept of deterioration of phase noise characteristics due to quantization noise in the fractional-N PLL circuit studied as a premise of the present invention; and

FIGS. 19A-19B are diagrams showing a concept of noise shaping and deterioration of phase noise characteristics due to a ΣΔ modulator in the fractional-N PLL circuit studied as a premise of the present invention.

### DESCRIPTIONS OF THE PREFERRED EMBODIMENTS

Hereinafter, embodiments of the present invention will be described in detail with reference to the accompanying drawings. Note that, components having the same function are denoted by the same reference symbols throughout the drawings for describing the embodiment, and the repetitive description thereof will be omitted. Also, unless otherwise stated, symbols denoting names of terminals will also denote names of lines and signals, and when a symbol denotes a power source, it also denotes a voltage value of the power source.

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

### First Embodiment

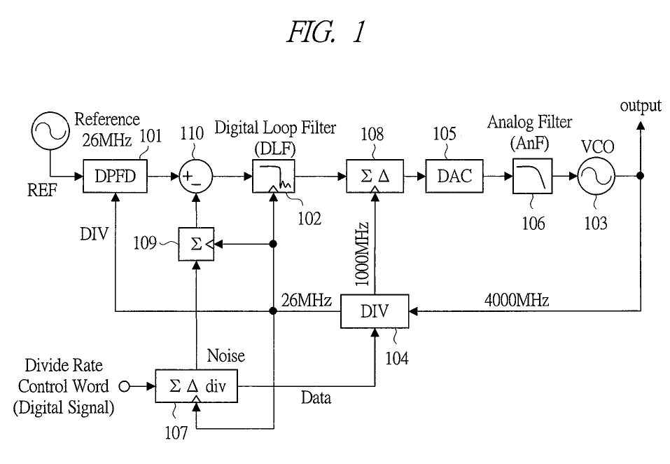

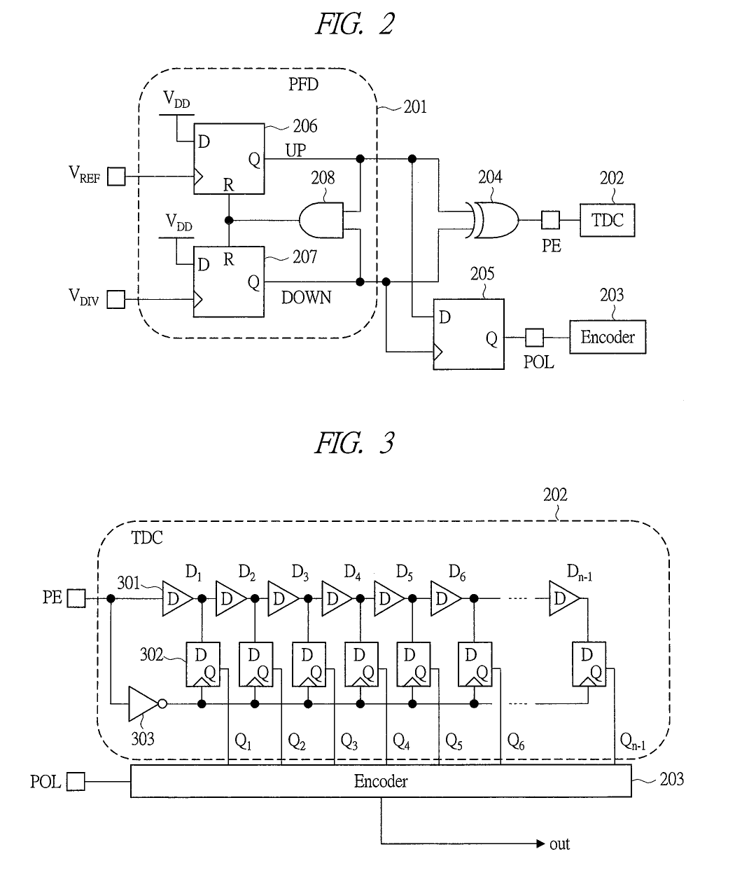

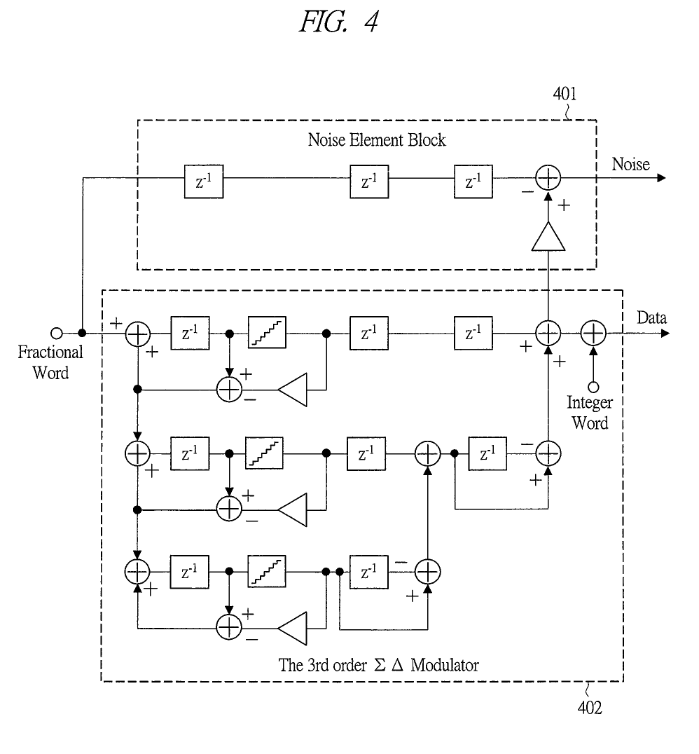

FIG. 1 is a block diagram showing a configuration example of a PLL (Phase-Locked Loop) according to a first embodiment of the present invention; FIG. 2 is a circuit diagram showing a configuration example of a digital phase frequency detector (DPFD) 101 in the PLL circuit according to the first embodiment; FIG. 3 is a circuit diagram showing a configuration example of a phase difference digital converter (TDC) 202 included in the DPFD; FIG. 4 is a circuit diagram showing a configuration example of a Sigma-Delta modulator (ΣΔdiv) 107; and FIG. 5 is a circuit diagram showing a configuration example of an analog filter (AnF) 106.

First, the example of the configuration of the PLL circuit according to the first embodiment will be described with reference to FIG. 1. The PLL circuit of the first embodiment is, for example, a semiconductor integrated circuit, which is formed on one semiconductor chip by a known semiconductor manufacturing technology.

The PLL circuit of FIG. 1 comprises such as: a digital phase frequency ratio detector (DPFD) 101; a digital loop filter (DLF) 102; a voltage control oscillator (VCO) 103; a frequency divider (DIV) 104; a digital-analog converter (DAC) 105; an analog filter (AnF) 106; a Sigma Delta modulator (ΣΔdiv) 107; a Sigma-Delta modulator (ΣΔ) 108; a integrator (Σ) 109; and an adder/subtractor 110.

A reference signal REF (e.g., 26 MHz) and an output from the frequency divider (DIV) 104 (frequency-divided signal DIV, e.g., 26 MHz) are inputted to the digital phase frequency detector (DPFD) 101. An output of the digital phase frequency detector (DPFD) 101 is inputted to an adding input of the adder/subtractor 110 and an output of the integrator (Σ) 109 is inputted to an subtracting input of the adder/subtractor 110. An output of the adder/subtractor 110 and an output of the frequency divider (DIV) 104 (e.g., 26 MHz) are inputted to the digital loop filter (DLF) 102. An output of the digital loop filter (DLF) 102 and an output (e.g., 1000 MHz) of the frequency divider (DIV) 104 are inputted to the Sigma Delta modulator (ΣΔ) 108. An output of the Sigma Delta modulator (ΣΔ) 108 is inputted to the digital-analog converter (DIV) 105. An output of the analog-digital converter (DAC) 105 is inputted to the analog filter (AnF) 106. An output of the analog filter (AnF) 106 is inputted to the voltage control oscillator (VCO) 103. An output (e.g., 4000 MHz) of the voltage control oscillator (VCO) 103 and an output (Data) of the Sigma Delta modulator (ΣΔdiv) 107 are inputted to the frequency divider (DIV) 104. A control signal (Divide Rate Control Word (Digital Signal)) and an output (e.g., 26 MHz) of the frequency divider (DIV) 104 are inputted to the Sigma Delta modulator (ΣΔdiv) 107. An output (Noise) of the Sigma Delta modulator (ΣΔdiv) 107 and an output (e.g., 26 MHz) of the frequency divider (DIV) 104 are inputted to the integrator (Σ) 109.

The digital phase frequency detector (DPFD) 101 detects (compares) phases and frequencies of the reference signal REF and the frequency-divided signal DIV and converts the same to a digital value. The digital loop filter (DLF) 102 eliminates high-frequency noise components from the output of the digital phase frequency detector 101. The digital-analog converter (DAC) 105 converts a digital value of the output of the digital loop filter 102 to an analog value. The analog filter (AnF) 106 eliminates high frequency noise components from the output of the digital-analog converter 105. The voltage control oscillator (VCO) 103 as an oscillator is controlled its frequency based on the output of the analog filter 106. The frequency divider (DIV) 104 divides the frequency of the output of the voltage control oscillator (VCO) 103 and outputs the frequency-divided signal DIV (feedback signal).

The Sigma Delta modulator (ΣΔ) 108 deforms quantization noise of the output of the digital loop filter 102 by its noise-shaping effect. The Sigma Delta modulator (ΣΔdiv) 107 and the integrator (Σ) eliminate digital noise components from the output of the digital phase frequency detector 101. Note that, the PLL circuit according to the first embodiment is a fractional-N PLL circuit.

Next, an operation of the PLL circuit according to the first embodiment will be described. A frequency of the output of the VCO 103 is divided by the DIV 104, and the DPFD 101 detects (compares) phases and frequencies of the reference signal REF and the frequency-divided signal DIV. A frequency divide rate of the DIV 104 is controlled by an external digital signal via the Sigma Delta modulator (ΣΔdiv) 107. After the phase detection (comparison), the adder/subtractor 110 subtracts fractional-N noise from the Sigma Delta modulator (ΣΔdiv) 107 and the integrator (Σ) 109 and inputs the result to the DLF 102 to filter the same. The output of the DLF 102 gets an effect by the noise-shaping effect in the Sigma Delta modulator (ΣΔ) 108 and converted to a voltage by the analog filter (AnF) 106 through the digital-analog converter (DAC) 105 so that the VCO 103 is controlled. The noise components (Noise) from the ΣΔdiv 107 is necessary to be converted from frequency to phase, thus it is once integrated by the integrator (Σ) 109 and then the output of the DPFD 101 is subjected to subtraction.

The outputs of the DIV 104 include a 1000 MHz output obtained by quarter-dividing the frequency of the VCO 103 and a 26 MHz output (same as the frequency of the reference signal REF).

A phase-difference digital converter (TDC: Time to Digital Control) which converts phase differences to be digital is used in the DPFD 101. FIG. 2 shows a configuration example of the DPFD 101. And, FIG. 3 shows a configuration example of the TDC 202.

As shown in FIG. 2, the DPFD 101 comprises: a PFD 201; the TDC 202; an encoder (Encoder) 203; an EX-OR gate 202; a flip-flop 205; etc. And the PFD 201 comprises: flip-flops 206, 207; an AND gate 208; etc. Further, as shown in FIG. 3, the TDC 202 comprises: a plurality of delay gates 301; a plurality of flip-flops 302; and an inverter gate 303; etc.

FIG. 4 shows a configuration example of the ΣΔ modulator (ΣΔdiv) 107 which controls the DIV 104. As shown in FIG. 4, the ΣΔdiv 107 comprises: a noise element block (Noise Element Block) 401; a third ΣΔ modulator (The 3rd ΣΔ Modulator) 402; etc. A control signal inputted from the external (Divide Rate Control Word) includes a fractional part (Fractional Word) and an integer part (Integer Word), and it inputs the fractional part to the 3rd ΣΔ modulator 402 and adds the integer part at an output portion to make a Data output. And, a value obtained by subtracting the fractional part from the ΣΔ output becomes Noise components. Note that, the configuration of the Sigma Delta modulator (ΣΔ) 108 is substantially same with that of the circuit of the 3rd ΣΔ modulator 402.

FIG. 5 shows a configuration example of the analog filter (AnF) 106. As shown in FIG. 5, the AnF 106 comprises: a resistor 501; and a capacitor 502; etc. High-frequency components are eliminated from the output of the DAC by this circuit.

Note that, the clock inputted to the ΣΔ 108 after the DLF 102 can be generated from the output of the VCO 103 by using another frequency divider other than being supplied from the DIV 104.

The PLL circuit of the present embodiment achieves the following effects according to the configuration described above.

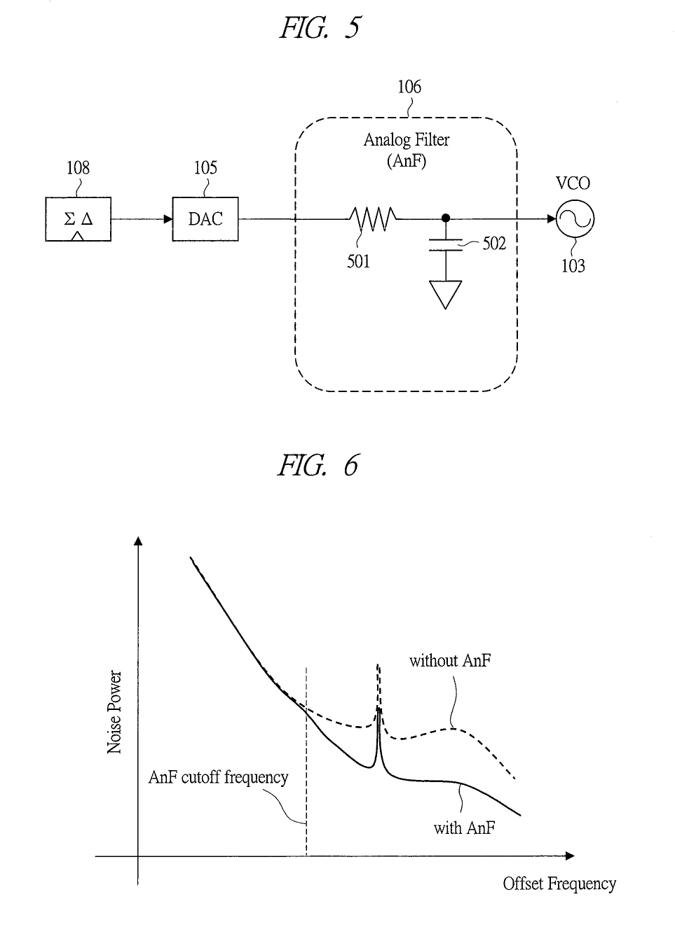

FIG. 6 is a conceptual diagram of phase noise characteristics in the case where the analog filter (AnF) 106. FIG. 6 shows a relationship between a noise power (Noise Power) and an offset frequency (Offset Frequency). In FIG. 6, the curve shown by a dotted line represents noise in the case where the AnF 106 is not used (without AnF). And, the curve shown by a solid line represents noise in the case where the AnF 106 is used (with AnF). Note that, the origin of the X axis of Offset Frequency corresponds to an oscillation frequency. And, the noise characteristics shown by the solid/dotted lines have spurious noise appeared due to the clock outputted from the DIV 104 and inputted to the DLF 102. As shown in FIG. 6, noise of higher offset frequency is reduced by the AnF 106. As apparent from FIG. 6, the quantization noise in the case where the DLF 102 and the ΣΔ modulator 108 are used can be suppressed by inserting the analog filter (AnF) 106 after the ΣΔ modulator 108. Further, the analog filter to be inserted is only necessary to eliminate noise generated by the noise-shaping effect of the ΣΔ modulator 108, and the cut-off frequency can be relatively high (from several tens of MHz). Accordingly, the analog filter AnF has a smaller area than an ALF (analog filter of several kHz cut-off frequency), and thus it can be mounted in a smaller area than the CP-PLL.

Since the analog filter AnF processes the noise components from the ΣΔdiv 107 without converting to a current value, the analog filter AnF can eliminate noise in a steady state more precisely than the CP-PLL does. The control of frequency divide rate in fractional-N type is done by digital values, thereby easily calculating the noise generated in a steady state. Therefore, the PLL circuit using DPFD 101 and the DLF 102 as the present embodiment can perform subtraction on the output of the DPFD 101 without converting noise to current values unlike Non-Patent Document 2. Consequently, noise can be precisely eliminated against variations.

Further, by using the DLF 102, the area-reduction effect according to process scaling is larger than that of the ALF. Still further, the DAC 105 and integrating circuits (e.g., Σ 109) can be made smaller by process scaling. Therefore, according to process scaling, the PLL circuit can be mounted in a smaller area than the conventional CP-PLL.

Moreover, the DIV 104, VCO 103 and the ΣΔdiv 107 can be achieved by conventional circuit configurations, and thus modulation methods thereof are not necessary to be changed from conventional ones. Therefore, changed parts from the CP-PLL can be fewer than the AD-PLL using a DCO.

### Second Embodiment

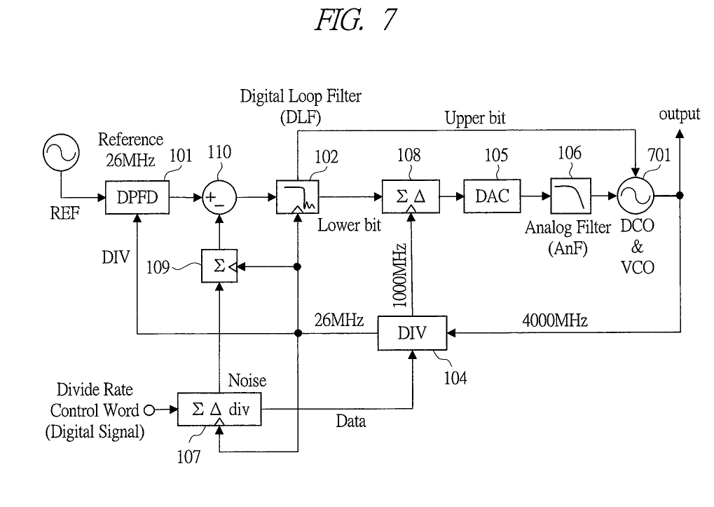

FIG. 7 is a block diagram showing a configuration example of a PLL (Phase-Locked Loop) circuit according to a second embodiment of the present invention.

As compared with the first embodiment, the PLL circuit according to the second embodiment has a same noise-elimination type of the fractional-N type but has a different configuration after the DLF 102. In the second embodiment, an oscillator (DCO & VCO) 701 is controlled by using upper bit side of the output of the DLF 102. A DCO (Digital Controlled Oscillator) part in the oscillator 701 performs coarse adjustment of frequency by digital control, and a VCO (Voltage Controlled Oscillator) part in the oscillator 701 performs fine adjustment of frequency by analog control. More particularly, upper bit (can be 1 bit or multiple bits) of the output of the DLF 102 is inputted to a digital control terminal of the oscillator 701 and lower bit (can be 1 bit or multiple bits) of the DLF 102 is inputted to the Sigma Delta modulator (ΣΔ) 108, and the output of the analog filter 106 is inputted to an analog control terminal of the oscillator 701.

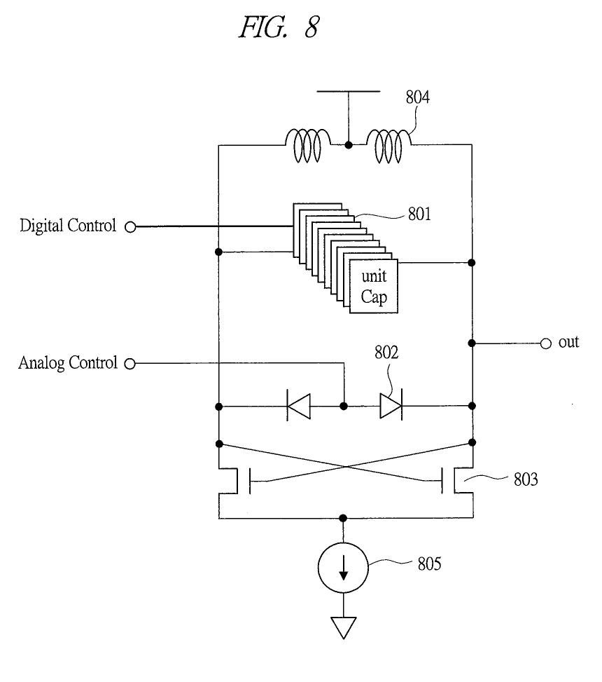

FIG. 8 shows a configuration example of the oscillator 701. FIG. 8 is an example of a configuration made by an LC oscillator. As shown in FIG. 8, a DCO part is configured by a plurality of unit capacitors (unit Cap) 801 and so forth. The overall capacitance value is controlled by switching the plurality of unit capacitors 801 by switches according to the input signal of the digital control terminal (Digital Control). The VCO part comprises: a diode 802; a transistor 803; a coil 804; and a current source 805; etc. An oscillation frequency (“out” in FIG. 8) of the oscillator 701 is controlled by an input voltage of the analog control terminal (Analog Control) and the capacitance values of the plurality of unit capacitors 801.

Therefore, according to the PLL circuit of the second embodiment, the number of bits inputted to the DAC 105 is reduced, and thus the ΣΔ 108 and the DAC 105 can be made smaller than those in the PLL circuit of the first embodiment. Accordingly, current and area can be reduced. Further, by increasing the number of upper bits of the DLF 102, the range of oscillation frequency can be extended.

### Third Embodiment

In a third embodiment, an application example of the PLL circuits of the first and second embodiments described above will be described.

FIG. 9 is a block diagram showing a configuration of a transceiving RF-IC for the pan-European digital cellular system GSM (BRIGHT).

The BRIGHT in FIG. 9 adopts a direct conversion system for data reception and an off-set PLL system for data transmission. A local oscillator and a frequency synthesizer 901 may adopt the PLL circuits of the first and second embodiments described above.

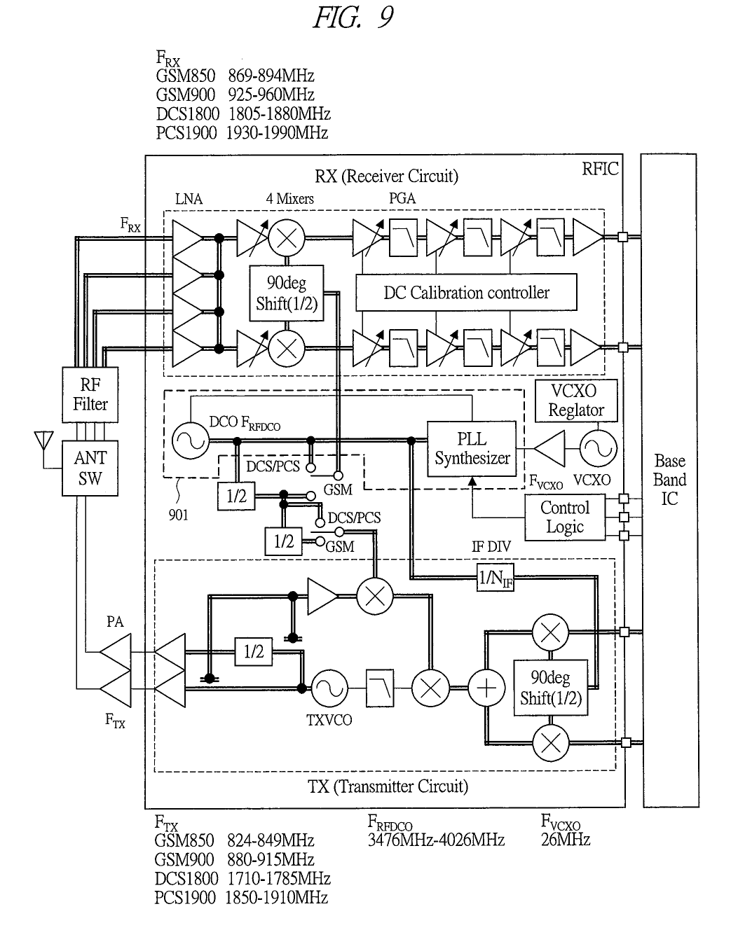

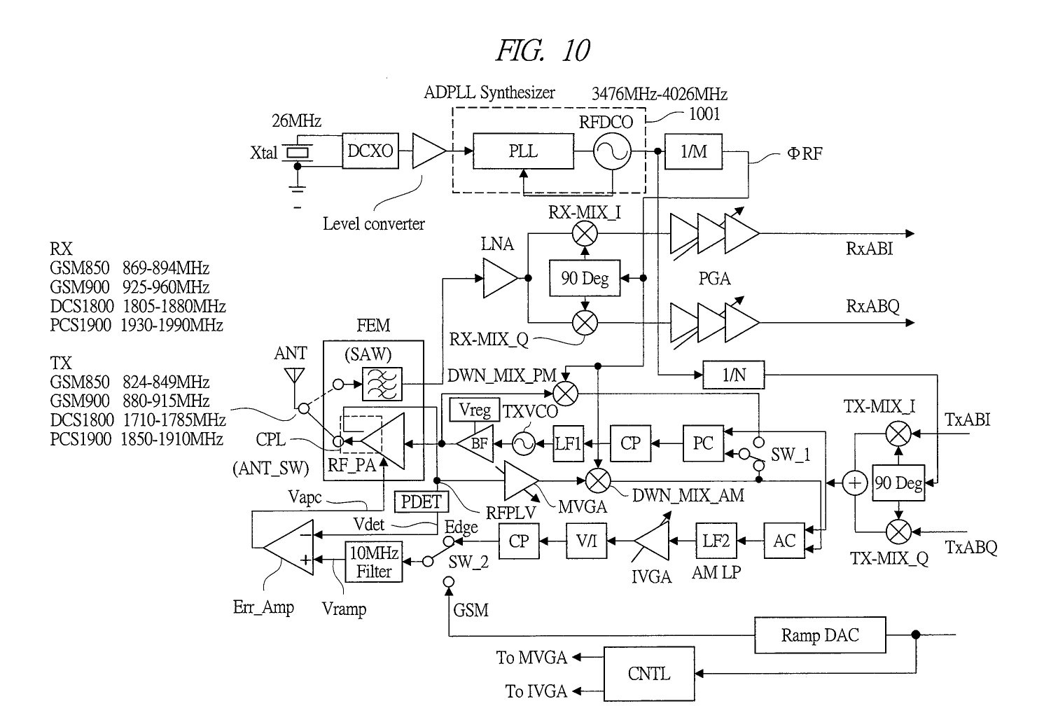

FIG. 10 is a block diagram showing a configuration of a transceiving RF-IC for the pan-European digital cellular system EDGE (BRIGHT).

The BRIGHT in FIG. 10 adopts a direct conversion system for data reception and a polar loop system for data transmission. A local oscillator and a frequency synthesizer 1001 may adopt the PLL circuits of the first and second embodiments described above.

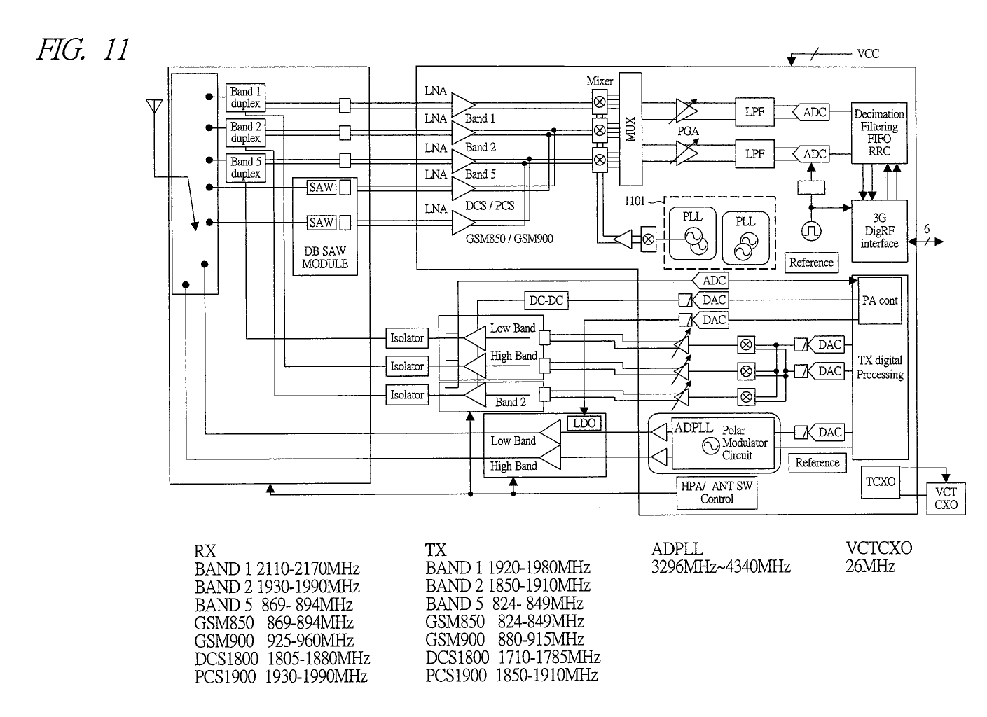

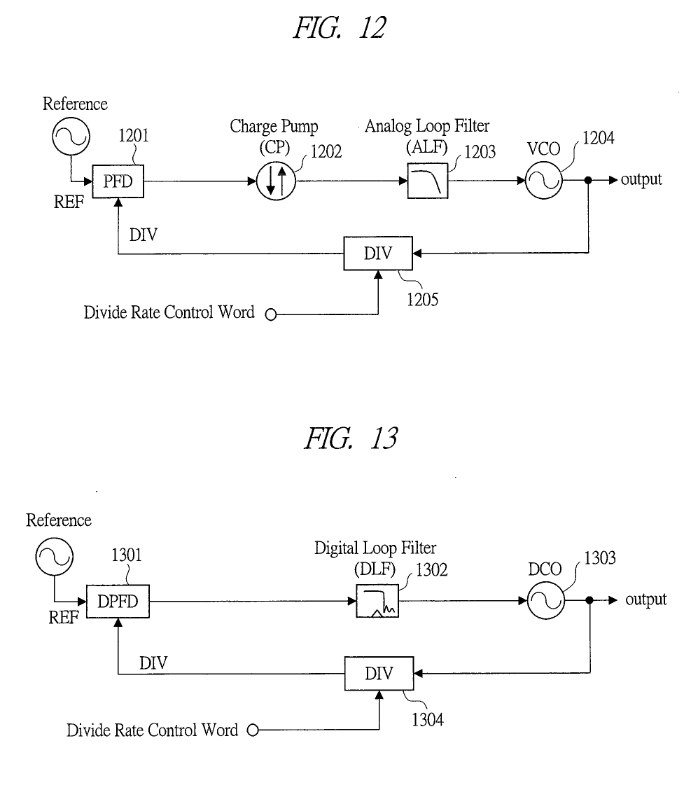

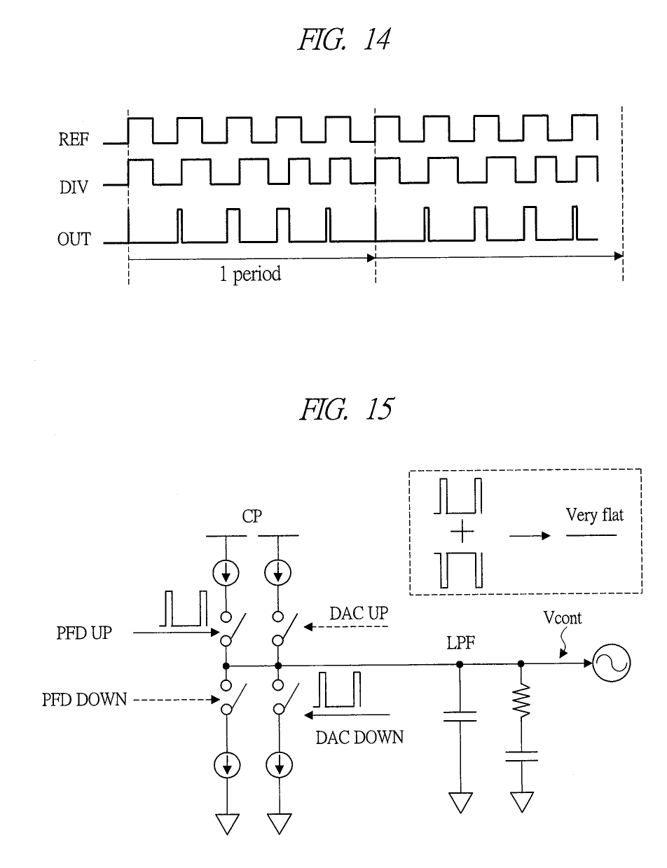

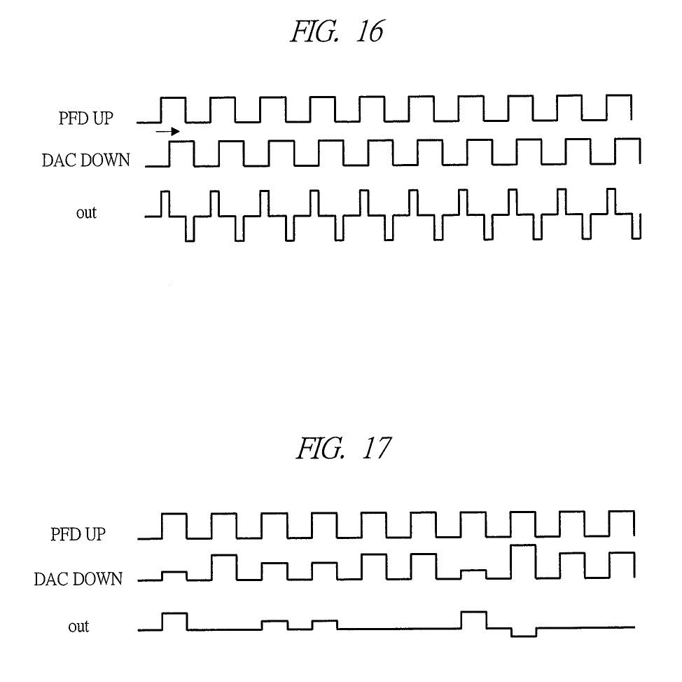

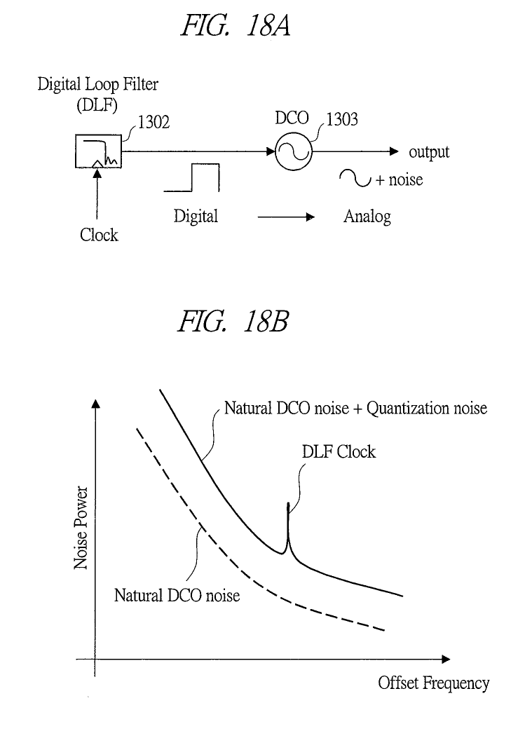

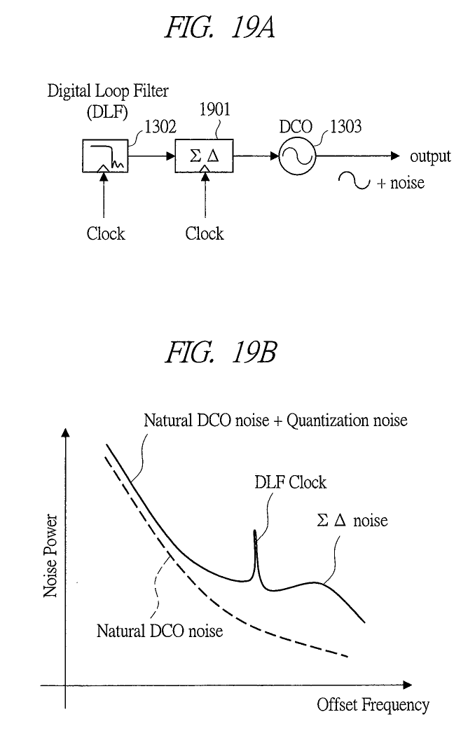

FIG. 11 is a block diagram showing a configuration of a transceiving RF-IC for the pan-European digital cellular system EDGE/WCDMA (BRIGHT).

The BRIGHT in FIG. 11 adopts a direct conversion system for data reception for both EDGE/WCDMA. Data transmission of WCDMA adopts a direct conversion system and that of EDGE adopts a polar modulation system comprising a phase modulation path which directly modulates the PLL and an amplitude modulation path. As a local oscillator 1101 for data reception of EDGE/WCDMA and data transmission of WCDMA adopts the PLL circuits of the first and second embodiments described above. And, the PLL circuits of the first and second embodiments are adopted for phase modulation of EDGE data transmission.

Further, the PLL circuits of the first and second embodiments can be generally adapted to RF-ICs for wireless LAN and other PLL frequency synthesizers.

In the foregoing, the invention made by the inventors of the present invention has been concretely described based on the embodiments. However, it is needless to say that the present invention is not limited to the foregoing embodiments and various modifications and alterations can be made within the scope of the present invention. Also, the first to third embodiments described above may be combined respectively in a suitable way.

The present invention is generally applicable to mobile phones, RF-ICs for wireless LAN and other PLL frequency synthesizers.

What is claimed is:

1. A PLL circuit comprising:
a digital phase frequency detector which compares phases and frequencies of a reference signal and a feedback signal and converts the same to a digital value;
a digital loop filter which eliminates high-frequency noise components from an output of the digital phase frequency detector;
a digital-analog converter which converts a digital value of an output of the digital loop filter to an analog value;
an analog filter which eliminates a high-frequency noise component from an output of the digital-analog converter;
an oscillator whose frequency is controlled based on an output of the analog filter; and
a frequency divider which divides the frequency of the oscillator and outputs the feedback signal.

2. The PLL circuit according to claim 1 further comprising a Sigma Delta modulator which eliminates quantization noise from the output of the digital loop filter.

3. The PLL circuit according to claim 1 further comprising a Sigma Delta modulator which eliminates digital noise components from the output of the digital phase frequency detector.

4. The PLL circuit according to claim 1, wherein
the oscillator comprises a digital control terminal and an analog control terminal,
an upper bit of the output of the digital loop filter is inputted to the digital control terminal of the oscillator, a lower bit of the output of the digital loop filter is inputted to the digital-analog converter side, and the output of the analog filter is inputted to the analog control terminal of the oscillator, and
the frequency of the oscillator is controlled based on input values of the digital control terminal and the analog control terminal.

5. The PLL circuit according to claim 1, wherein
the PLL circuit is a fractional-N type PLL circuit.
